(19) United States
(12) Patent Application Publication
(10) Pub. No.: US 2025/0243040 A1
(43) Pub. Date: Jul. 31, 2025

(54) HOIST AND HOISTING SYSTEM FOR IMMERSION COOLING TANK

(71) Applicant: Fulian Precision Electronics (Tianjin) Co., Ltd., Tianjin (CN)

(72) Inventors: MING-HUA DUAN, Tianjin (CN); Fang-Xing Yang, Tianjin (CN); Han-Yu Li, New Taipei (TW)

(21) Appl. No.: 18/674,991

(22) Filed: May 27, 2024

(30) Foreign Application Priority Data
Jan. 31, 2024 (CN) 202410138381.3

(51) Int. Cl. B66D 1/60; B66C 1/34; B66D 1/06; H05K 7/20

(52) U.S. Cl. CPC B66D 1/60; B66C 1/34; B66D 1/06; H05K 7/20236; B66D 2700/023

(57) ABSTRACT

A hoist for hoisting servers of an immersion cooling tank comprises a guide, a moving base, a hoisting arm, a hanging component, a drive component. The guide is located on the immersion cooling tank and extended horizontally. The moving base is located on the guide and movable along the guide. The hoisting arm is located on the moving base and is rotatable relative to the moving base around a vertical axis. The hanging component is used for hanging the server. The drive component is located on the hoisting arm and is connected to the hanging component. The drive component is used for lifting and dropping the hanging component and the server hanged on the hanging component. A hoisting system is also disclosed.

### FIELD

The disclosure herein generally relates to internet data centers, and more particularly relates to a hoist and a hoisting system for immersion cooling tank.

### BACKGROUND

In internet data centers, servers are usually placed in immersion cooling tanks for cooling. However, servers are heavy to carry, causing difficult transportation of servers into or out of the immersion cooling tanks.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an embodiment of a hoisting system according to the present disclosure.

FIG. 2 is an isometric view of a hoist of the hositing system shown in FIG. 1.

FIG. 3 is a partial isometric view of the hoist shown in FIG. 2.

FIG. 4 is a partial isometric view of the hoist shown in FIG. 3.

FIG. 5 is another isometric view of the hoisting system shown in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only and are not intended to limit the present disclosure.

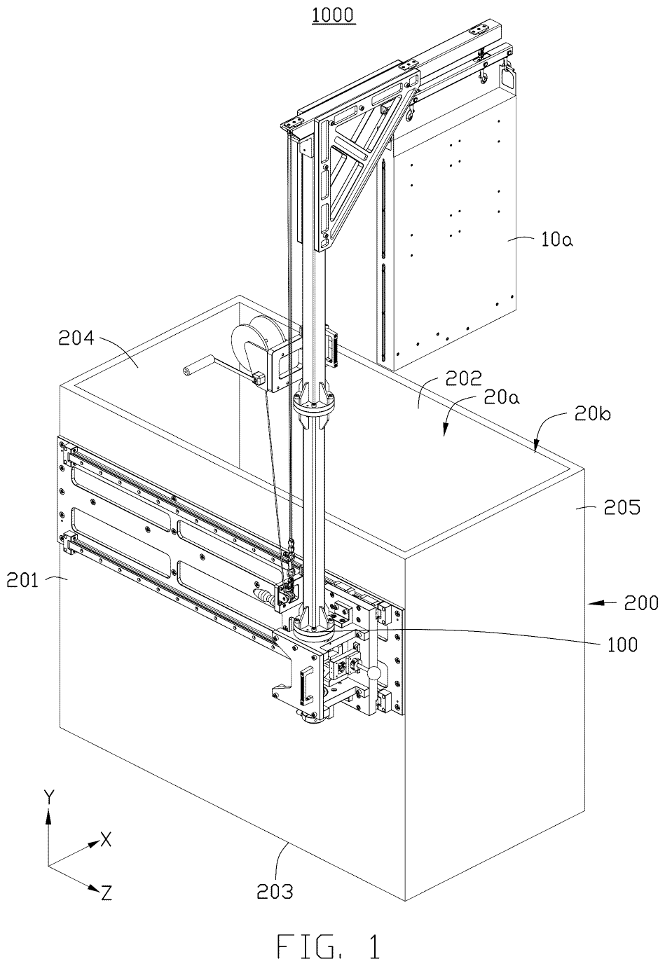

As shown in FIG. 1 to FIG. 5, a hoisting system 1000 in an embodiment includes an immersion cooling tank 200 and a hoist 100. The hoist 100 is mounted on the immersion cooling tank 200. Servers 10a are placed in the immersion cooling tank 200 for cooling. The hoist 100 is used for moving the servers 10a into or out of the immersion cooling tank 200.

In some embodiments, the server 10a can be replaced by computers, monitors, internet switches, or routers and so on.

In some embodiments, as shown in FIG. 1, the immersion cooling tank 200 includes a first vertical wall 201 and a second vertical wall 202 facing to each other in a first direction X. A cavity 20a is formed in the immersion cooling tank 200 between the first vertical wall 201 and the second vertical wall 202 to accommodate the servers 10a. An opening 20b is defined on the top of the immersion cooling tank 200, and the opening 20b is connected to the cavity 20a and open to a second direction Y. The immersion cooling tank 200 has coolant in the cavity 20a, and the servers 10a are immerged in the coolant. The hoist 100 is used for hanging the servers 10a out of the immersion cooling tank 200 through the opening 20b or putting the servers 10a into the immersion cooling tank 200 through the opening 20b.

In some embodiments, as shown in FIG. 1, the immersion cooling tank 200 further includes a bottom wall 203, a third vertical wall 204, and a fourth vertical wall 205. The third vertical wall 204 and the fourth vertical wall 205 facing to each other in a third direction Z. The bottom wall 203 is connected to the bottom of the first vertical wall 201, the second vertical wall 202, the third vertical wall 204, and the fourth vertical wall 205. The first vertical wall 201, the second vertical wall 202, the bottom wall 203, the third vertical wall 204 and the fourth vertical wall 205 forms the cavity 20a.

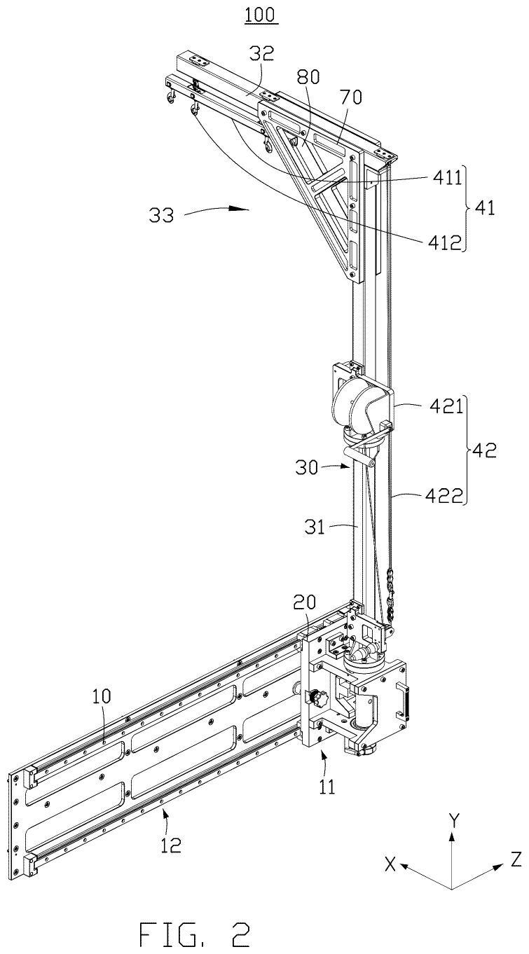

In some embodiments, as shown in FIG. 2, the hoist 100 includes a guide 10, a moving base 20, a hoisting arm 30, a hanging component 41, and a drive component 42. The guide 10 is mounted on the immersion cooling tank 200. The moving base 20 is connected to the guide 10 and is slidable along the guide 10. The hoisting arm 30 is connected to the moving base 20 and the hoisting arm 30 is rotatable around an axis vertical. The hanging component 41 is used for hanging the servers 10a. The drive component 42 is located on the hoisting arm 30 and is connected to the hanging component 41. The drive component 42 is used for lifting and dropping the hanging component 41 and the server 10a hanged on the hanging component 41.

For example, when the hoist 100 moves a server 10a into the immersion cooling tank 200: the moving base 20 moves the hoisting arm 30 along the guide 10, and the hoisting arm 30 rotates until the hanging component 41 is above the server 10a; the drive component 42 drops the hanging component 41 down for connecting the hanging component 41 and the server 10a; after the hanging component 41 and the server 10a are connected, the drive component 42 lifts the hanging component 41 and the server 10a up, then the hoisting arm 30 rotates and the moving base 20 moves the hoisting arm 30 along the guide 10 until the server 10a is above the target position in the immersion cooling tank 200; the drive component 42 drops the hanging component 41 and the server 10a until the server 10a is put in position in the immersion cooling tank 200.

Compared with conventional cranes on the ground, the hoist 100 can be directly assembled with the immersion cooling tank 200. It saves the position adjustment and calibration steps between the hoist 100 and the immersion cooling tank 200, which helps to improve the convenience and accuracy of the hoist 100. Moreover, the hoist 100 does not need to be placed on the ground, which helps reduce the occupied space.

In some embodiments, as shown in FIG. 1 and FIG. 2, the guide 10 is horizontal and is parallel to the third direction Z. The drive component 42 moves the hanging component 41 in the second direction Y, which is vertical.

In some embodiments, as shown in FIG. 1 and FIG. 2, the guide 10 is mounted on the outside surface of first vertical wall 201, which is convenient to assemble the hoist 100 and the immersion cooling tank 200.

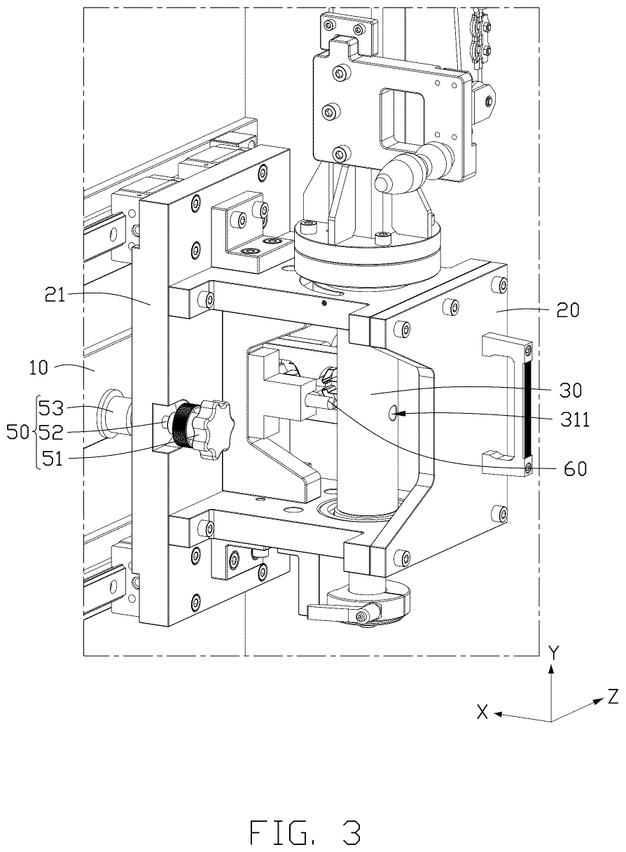

In some embodiments, a bearing is set between the hoisting arm 30 and the moving base 20 to realize the rotation between the hoisting arm 30 and the moving base 20. In some embodiments, as shown in FIG. 3, the hoist 100 further includes a first locking component 50. The first locking component 50 is mounted on the moving base 20. The first locking component 50 defines a first locking state and a first unlocking state. When the first locking component 50 is in the first locking state, the first locking component 50 is used to stop the movement of the moving base 20. When the first locking component 50 is in the first unlocking state, the first locking component 50 releases the moving base 20 to allow the moving base 20 to move.

In some embodiments, as shown in FIG. 3, the first locking component 50 includes a knob 51, a threaded rod 52, and a head 53 connected in sequence. Users rotates the knob 51 to rotate threaded rod 52. The threaded rod 52 extends through the moving base 20 and is threaded with the moving base 20 by screw. The head 53 is located between the moving base 20 and the guide 10. When the knob 51 is rotated, the threaded rod 52 and the head 53 rotates with the knob 51, and the threaded rod 52 moves the head 53 closer to or away from the guide 10 according to the clockwise or counterclockwise rotation of the knob 51 because of the threaded connection between the moving base 20 and the threaded rod 52. When the first locking component 50 is in the first locking state, the head 53 is against the guide 10 to stop the moving base 20. When the first locking component 50 is in the first unlocking state, the head 53 is not in contact with the guide 10 to allow the moving base 20 to move.

When the head 53 is against the guide 10, the friction between the head 53 and the guide 10 stops the moving base 20 from moving. Therefore, the moving base 20 can be locked to any position on the guide 10, thereby achieving stepless adjustment of the fixed positions of the moving base 20.

In some embodiments, the head 53 is made of elastic rubber to improve the friction between the head 53 and the guide 10.

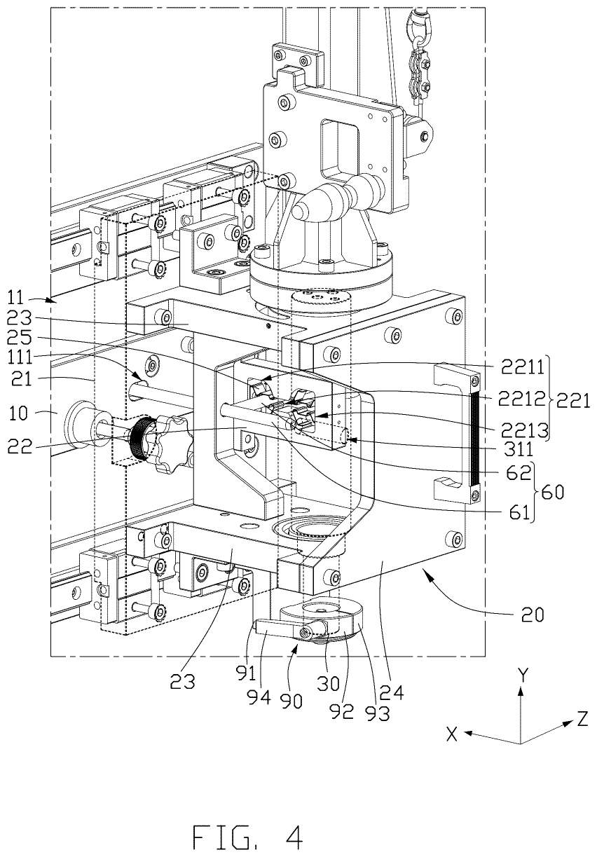

In some embodiments, as shown in FIG. 3 and FIG. 4, the hoist 100 further includes a second locking component 60. The second locking component 60 is mounted on the moving base 20. The second locking component 60 defines a second locking state and a second unlocking state. When the second locking component 60 is in the second locking state, the second locking component 60 stops the hoisting arm 30 from rotating. When the second locking component 60 is in the second unlocking state, the second locking component 60 releases the hoisting arm 30 to allow the hoisting arm 30 to rotate.

When the hoisting arm 30 does not need to rotate, the second locking component 60 can prevent the hoisting arm 30 from accidentally rotating. When the hoist 100 is not in use, the second locking component 60 can position the hoisting arm 30 at an angle that takes up less space, which is beneficial to reducing the space occupied. When the hoist 100 is in use, the second locking component 60 improves accuracy and security.

In some embodiments, as shown in FIG. 3 and FIG. 4, the second locking component 60 includes a pin rod 61 and an accessory rod 62. The pin rod 61 is perpendicularly connected to the accessory rod 62, and the accessory rod 62 is movable relative to the moving base 20. The hoisting arm 30 has a positioning hole 311. When the second locking component 60 is in the second locking state, the accessory rod 62 moves the pin rod 61 to insert the pin rod 61 into the positioning hole 311, to stop the rotation of the hoisting arm 30. When the second locking component 60 is in the second unlocking state, the accessory rod 62 moves the pin rod 61 out of the positioning hole 311, to release the hoisting arm 30.

In some embodiments, as shown in FIG. 3 to FIG. 5, the moving base 20 includes a sliding piece 21 and a supporting piece 22. The sliding piece 21 is slidably connected to the guide 10, and the supporting piece 22 is mounted on the sliding piece 21. The supporting piece 22 has a guiding hole 221. The accessory rod 62 extents through the guiding hole 221 in the direction Z and is movable in the direction X. The guiding hole 221 has an unlocking section 2211, a transitional section 2212, and a locking section 2213 connected in sequence. The accessory rod 62 moves between the unlocking section 2211 and the locking section 2213 through the transitional section 2212. When the second locking component 60 is in the second unlocking state, the accessory rod 62 is in the unlocking section 2211. When the second locking component 60 is in the second locking state, the accessory rod 62 is in the transitional section 2212. Two leaf springs 25 are placed in the unlocking section 2211 and the locking section 2213, respectively. The leaf springs 25 is used for clipping the accessory rod 62 to position the accessory rod 62 and the sliding piece 21. Also, the leaf springs 25 make it easier for users to judge the location of the pin rod 61 and the accessory rod 62.

In some embodiments, as shown in FIG. 4, the moving base 20 further includes two fixing boards 23 facing to each other in the second direction Y, and the hoisting arm 30 is rotatably connected to the two fixing boards 23. For example, the hoisting arm 30 is connected to the two fixing board 23 by bearings.

In some embodiments, the moving base 20 further includes a cover board 24, the cover board 24 is fixed to the two fixing boards 23 by screws.

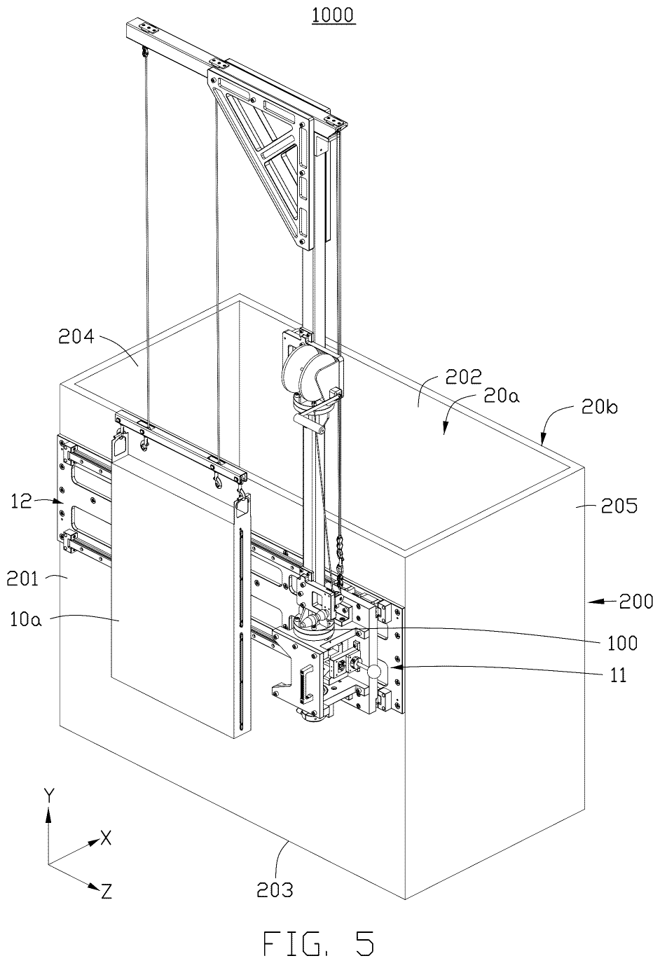

In some embodiments, as shown in FIG. 4 and FIG. 5, the guide 10 defines a picking position 11 and an unpicking position 12 for the moving base 20. The guide 10 has an avoiding hole 111 at the picking position 11. The pin rod 61 can insert into the avoiding hole 111. When the moving base 20 is on the unpicking position 12, the guide 10 blocks the pin rod 61 from moving out of the positioning hole 311, so the hoisting arm 30 cannot rotate. When the moving base 20 is on the picking position 11, the pin rod 61 can insert into the avoiding hole 111, so the pin rod 61 can move out of the positioning hole 311, to allow the hoisting arm 30 to rotate. Thus, the hoisting arm 30 can only rotate at the picking position 11, which prevents the hoisting arm 30 from rotating at the unpicking position 12 and prevents the hoisting arm 30 from hitting the users, thereby improving the safety of the hoisting arm 30.

In some embodiments, as shown in FIG. 4 and FIG. 5, the hoist 100 further includes clipping component 90, and the clipping component 90 includes a connecting board 91, a first clipping arm 92, a second clipping arm 93, and a tightening piece 94. The connecting board 91 is fixed on the fixing board 23. The first clipping arm 92 and the second clipping arm 93 is connected to the connecting board 91. The first clipping arm 92 and the second clipping arm 93 clip the hoisting arm 30. The tightening piece 94 extends through the first clipping arm 92 and is connected to the second clipping arm 93. The tightening piece 94 is rotatable relative to the first clipping arm 92, to move the second clipping arm 93 closer to or away from the first clipping arm 92, so the first clipping arm 92 and the second clipping arm 93 can clip the hoisting arm 30 tightly to stop the hoisting arm 30 from rotating, or the first clipping arm 92 and the second clipping arm 93 release the hoisting arm 30 to allow the hoisting arm 30 to rotate.

As shown in FIG. 4 and FIG. 5, when the moving base 20 is on the picking position 11, users insert the pin rod 61 into the avoiding hole 111 to position the moving base 20. Then users rotate the tightening piece 94, letting the first clipping arm 92 and the second clipping arm 93 clip the hoisting arm 30 tightly to stop the hoisting arm 30 from rotating, improving the stability, accuracy, and safety of the hoisting arm 30 when hoisting servers 10a.

In some embodiments, the tightening piece 94 can be a combination of a bolt and a handle. The first clipping arm 92 is provided with a hole for the tightening piece 94 to pass through, and the second clipping arm 93 is provided with a threaded hole for connecting with the tightening piece 94.

In some embodiments, as shown in FIG. 2, the hoisting arm 30 has a first arm 31 and a second arm 32 connected to each other. The first arm 31 is rotatably connected to the moving base 20. The second arm 32 is horizontal, and the first arm 31 is vertical. An avoiding space 33 is formed between the second arm 32 and the first arm 31. The hanging component 41 is placed in the avoiding space 33.

In some embodiments, as shown in FIG. 2, the drive component 42 includes a pulley 421 and a rope 422. The pulley 421 is mounted on the hoisting arm 30. the rope 422 extends along the first arm 31 and the second arm 32. The pulley 421 and the hanging component 41 are connected by the rope 422. When users rotate the pulley 421, the rope 422 moves the hanging component 41 up or down according to the clockwise or counterclockwise rotation of the pulley 421.

In some embodiments, as shown in FIG. 2, the hanging component 41 includes a hanging rod 411 and a plurality of hooks 412. The hanging rod 41 is connected to the rope 422. The plurality of hooks 412 are used for hooking the server 10a.

In some embodiments, as shown in FIG. 2, the hoist 100 further includes a first stiffener 70 and a second stiffener 80. The first stiffener 70 and the second stiffener 80 are located on opposite sides of the first arm 31 and the second arm 32. The first stiffener 80 and the second stiffener 90 are both connected to the first arm 31 and the second arm 32, improving the stability of the connection between the first arm 31 and the second arm 32 and improving the load capacity of the hoisting arm 30.

In some embodiments, the first stiffener 70 and the second stiffener 80 is triangle.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A hoist for hoisting servers of an immersion cooling tank, the hoist comprising:
a guide located on the immersion cooling tank and extended horizontally;
a moving base located on the guide and movable along the guide;
a hoisting arm located on the moving base and rotatable relative to the moving base around a vertical axis;
a hanging component configured for hanging the server; and
a drive component located on the hoisting arm and connected to the hanging component, the drive component being configured for lifting and dropping the hanging component and the server hanged on the hanging component.

2. The hoist of claim 1 further comprises a first locking component, the first locking component is located on the moving base, the first locking component defines a first locking state and a first unlocking state, when the first locking component is in the first locking state, the first locking component stops the moving base from moving, and when the first locking component is in the first unlocking state, the first locking component releases the moving base.

3. The hoist of claim 2, wherein the first locking component comprises a knob, a threaded rod, and a head, the threaded rod extends through the moving base and is threaded with the moving base, the knob is mounted on the threaded rod and is located on a side of the moving base away from the guide, the head is mounted on the threaded rod and is located between the moving base and the guide, when the knob is rotated, the threaded rod and the head rotates with the knob, and the threaded rod moves the head closer to or away from the guide according to the clockwise or counterclockwise rotation of the knob, when the first locking component is in the first locking state, the head is against the guide to stop the moving base, and when the first locking component is in the first unlocking state, the head and the guide are not in contact to release the moving base.

4. The hoist of claim 1 further comprises a second locking component, the second locking component is located on the moving base, the second locking component defines a second locking state and a second unlocking state, when the second locking component is in the second locking state, the second locking component stops the hoisting arm from rotating, and when the second locking component is in the second unlocking state, the second locking component releases the hoisting arm.

5. The hoist of claim 4, wherein the second locking component comprises a pin rod and an accessory rod, the pin rod is perpendicularly connected to the accessory rod, the accessory rod is movable relative to the moving base, the hoisting arm defines a positioning hole, when the second locking component is in the second locking state, the accessory rod moves the pin rod to insert into the positioning hole to stop the hoisting arm from rotating, when the second locking component is in the second unlocking state, the accessory rod moves the pin rod out from the positioning hole to allow the hoisting arm to rotate.

6. The hoist of claim 5, wherein the moving base comprises a sliding piece and a supporting piece, the sliding piece is connected to the guide and slidable along the guide, the supporting piece is mounted on the sliding piece, the supporting piece defines a guiding hole extended in direction of movement of the pin rod, the accessory rod extends through the guiding hole and is movable in the guiding hole, the guiding hole defines a unlocking section, a transitional section, and a locking section connected in sequence, the accessory rod is movable between the unlocking section and the locking section through the transitional section, when the second locking component is in the second unlocking state, the accessory rod is in the unlocking section, when the second locking component is in the second locking state, the accessory rod is in the locking section, two leaf springs are located in the unlocking section and the locking section, respectively, each of the two leaf springs is configured for positioning the accessory rod.

7. The hoist of claim 1, wherein the hoisting arm comprises a first arm and a second arm, the first arm extends vertically and is rotatably connected to the moving base, the first arm is connected to the second arm, the second arm extends horizontally and is connected to a top of the first arm, an avoiding space is defined by the second arm and the first arm, the hanging component is connected to the second arm and moves in the avoiding space.

8. The hoist of claim 7, wherein the drive component comprises a pulley and a rope, the pulley is mounted on the hoisting arm, the rope extends along the first arm and the second arm, and the rope connects the pulley and the hanging component, when the pulley is rotated, the rope lifts or drops the hanging component and the server hanged on the hanging component.

9. The hoist of claim 7 further comprises a first stiffener and a second stiffener, the first stiffener and the second stiffener are located on opposite sides of the first arm and the second arm, the first stiffener and the second stiffener are both connected to the first arm and the second arm.

10. The hoist of claim 7, wherein the hanging component comprises a hanging rod and a plurality of hooks, the plurality of hooks are mounted on the hanging rod, the hanging rod is connected to the rope, each of the plurality of hooks is configured for hooking the server.

11. A hoisting system for immersion cooling, the hoisting system comprising:
an immersion cooling tank comprising a first vertical wall and a second vertical wall facing to each other, and a cavity being defined in the immersion cooling tank between the first vertical wall and a second vertical wall to accommodate servers, and an opening being defined on a top of the immersion cooling tank; and
a hoist for hoisting servers of the immersion cooling tank, wherein the hoist comprises:
a guide located on the first vertical wall outside the cavity and extended horizontally;
a moving base located on the guide and movable along the guide;
a hoisting arm located on the moving base and rotatable relative to the moving base around a vertical axis;
a hanging component configured for hanging the servers; and
a drive component located on the hoisting arm and connected to the hanging component, the drive component being configured for lifting and dropping the hanging component and the server hanged on the hanging component to move the servers into or out of the cavity.

12. The hoisting system of claim 11, wherein the hoist further comprises a first locking component, the first locking component is located on the moving base, the first locking component defines a first locking state and a first unlocking state, when the first locking component is in the first locking state, the first locking component stops the moving base from moving, and when the first locking component is in the first unlocking state, the first locking component releases the moving base.

13. The hoisting system of claim 12, wherein the first locking component comprises a knob, a threaded rod, and a head, the threaded rod extends through the moving base and is threaded with the moving base, the knob is mounted on the threaded rod and is located on a side of the moving base away from the guide, the head is mounted on the threaded rod and is located between the moving base and the guide, when the knob is rotated, the threaded rod and the head rotates with the knob, and the threaded rod moves the head closer to or away from the guide according to the clockwise or counterclockwise rotation of the knob, when the first locking component is in the first locking state, the head is against the guide to stop the moving base, and when the first locking component is in the first unlocking state, the head and the guide are not in contact to release the moving base.

14. The hoisting system of claim 11, wherein the hoist further comprises a second locking component, the second locking component is located on the moving base, the second locking component defines a second locking state and a second unlocking state, when the second locking component is in the second locking state, the second locking component stops the hoisting arm from rotating, and when the second locking component is in the second unlocking state, the second locking component releases the hoisting arm.

15. The hoisting system of claim 14, wherein the second locking component comprises a pin rod and an accessory rod, the pin rod is perpendicularly connected to the accessory rod, the accessory rod is movable relative to the moving base, the hoisting arm defines a positioning hole, when the second locking component is in the second locking state, the accessory rod moves the pin rod to insert into the positioning hole to stop the hoisting arm from rotating, when the second locking component is in the second unlocking state, the accessory rod moves the pin rod out from the positioning hole to allow the hoisting arm to rotate.

16. The hoisting system of claim 15, wherein the moving base comprises a sliding piece and a supporting piece, the sliding piece is connected to the guide and slidable along the guide, the supporting piece is mounted on the sliding piece, the supporting piece defines a guiding hole extended in direction of movement of the pin rod, the accessory rod extends through the guiding hole and is movable in the guiding hole, the guiding hole defines a unlocking section, a transitional section, and a locking section connected in sequence, the accessory rod is movable between the unlocking section and the locking section through the transitional section, when the second locking component is in the second unlocking state, the accessory rod is in the unlocking section, when the second locking component is in the second locking state, the accessory rod is in the locking section, two leaf springs are located in the unlocking section and the locking section, respectively, each of the two leaf springs is configured for positioning the accessory rod.

17. The hoisting system of claim 11, wherein the hoisting arm comprises a first arm and a second arm, the first arm extends vertically and is rotatably connected to the moving base, the first arm is connected to the second arm, the second arm extends horizontally and is connected to a top of the first arm, an avoiding space is defined by the second arm and the first arm, the hanging component is connected to the second arm and moves in the avoiding space.

18. The hoisting system of claim 17, wherein the drive component comprises a pulley and a rope, the pulley is mounted on the hoisting arm, the rope extends along the first arm and the second arm and the rope connects the pulley and the hanging component, when the pulley is rotated, the rope lifts or drops the hanging component and the server hanged on the hanging component.

19. The hoisting system of claim 17, wherein the hoist further comprises a first stiffener and a second stiffener, the first stiffener and the second stiffener are located on opposite sides of the first arm and the second arm, the first stiffener and the second stiffener are both connected to the first arm and the second arm.

20. The hoisting system of claim 17, wherein the hanging component comprises a hanging rod and a plurality of hooks, the plurality of hooks are mounted on the hanging rod, the hanging rod is connected to the rope, each of the plurality of hooks is configured for hooking the server.
